(19) United States
(12) Patent Application Publication
(10) Pub. No.: US 2014/0185247 A1
(43) Pub. Date: Jul. 3, 2014

(54) LATCH TO POSITION AND BIAS A MODULE WITHIN A CHASSIS

(71) Applicant: INTERNATIONAL BUSINESS MACHINES CORPORATION, (US)

(72) Inventors: Karl K. Dittus, Durham, NC (US); David J. Jensen, Raleigh, NC (US); Brian A. Trumbo, Apex, NC (US)

(73) Assignee: INTERNATIONAL BUSINESS MACHINES CORPORATION, Armonk, NY (US)

(21) Appl. No.: 13/729,404

(22) Filed: Dec. 28, 2012

(51) Int. Cl. H05K 7/02

(52) U.S. Cl. CPC H05K 7/02
USPC 361/728

(57) ABSTRACT

A system includes a module having a connector at a leading end and a handle pivotally coupled to a trailing end. The handle pivots between open and closed positions, and includes landing and grip portions. The system further includes a chassis having a bay, a connector disposed in the bay, and a spring latch assembly adjacent an open end of the bay for receiving the leading end of the module. The spring latch has a catch adjacent to a spring element. Receiving the leading end of the module into the bay aligns the module connector with the connector in the bay and aligns the landing of the handle with the catch of the spring latch assembly. Pivoting the handle from the open position to the closed position will then cause the landing of the handle to engage the catch and then load the spring element to couple the connectors.

### BACKGROUND OF THE INVENTION

1. Field of the Invention

The present invention relates to an apparatus to position and to bias a connector on an electronic module into engagement with a corresponding connector in a chassis.

2. Background of the Related Art

A modular electronic component, or module, is connected to another electronic device using a connector to enable the communication of data signals there between. For example, a module, having a connector, may send signals through the connector and to a second electronic device also having a connector that is engaged with the connector on the module. Connectors for electronic devices come in a variety of configurations including, but not limited to, pin and socket, pin and sleeve, parallel port, USB and serial connectors, to name a few. The connectors of the module and the second electronic device may be directly engaged or indirectly engaged through an intermediate structure, such as a midplane installed in a computer chassis.

A midplane is generally an electronic interface installed within a chassis to support one or more electronic connectors on a front side and, optionally, one or more electronic connectors on a back side. A module having a connector may be coupled to a connector on the front side of the midplane or to a connector on the back side of the midplane. The two connectors generally require an insertion force in order to make up the connection. These types of connections may also be considered to be blind mate connections since the two connectors are out of view as they are being connected. Accordingly, the only point of control over the make up of the connection is at a distal end of the module.

Connectors for electronic devices are generally manufactured to function notwithstanding normal manufacturing variations in the dimensions of the connectors. For example, a connector on a midplane and a corresponding connector on a module are each manufactured within certain tolerances to ensure that the sockets of the connector on the midplane will align with and receive the pins of the connector on the module and to ensure that when the pins of the module connector are received within the sockets of the midplane connector, the pins conductively engage the corresponding contacts in the connector on the midplane. To ensure conductive engagement between the pins and the contacts, the pins in the connector on the module are generally elongate in the direction of insertion into the sockets so that any variance in the depth of the corresponding sockets or the position of the contacts in the midplane connector does not prevent conductive engagement between the pins and the contacts of the connectors.

### BRIEF SUMMARY OF THE INVENTION

The present invention provides a system comprising a module having a connector at a leading end of the module and a handle pivotally coupled to a trailing end of the module to pivot between an open position and a closed position, wherein the handle has a landing and a grip portion. The system further comprises a chassis having a bay, a connector disposed at a distal end of the bay, and a spring latch assembly connected to the chassis adjacent a proximal end of the bay, wherein the proximal end of the bay is open to receive the leading end of the module, and wherein the spring latch has a catch adjacent to a spring element. Receiving the leading end of the module into the bay to a first position aligns the connector on the module with the connector in the bay of the chassis and aligns the landing of the handle with the catch of the spring latch assembly. With the module in the first position in the bay, pivoting the handle from the open position to the closed position causes the landing of the handle to engage the catch of the spring latch assembly and then load the spring element, wherein loading the spring element imparts a reactive force to engage the connector on the module with the aligned connector disposed in the distal end of the bay.

### BRIEF DESCRIPTION OF THE SEVERAL VIEWS OF THE DRAWINGS

FIG. 1 is a plan view of a bay in a chassis receiving an electronic module to position a connector on the leading end of the module in close proximity and alignment with a corresponding connector within the bay.

FIG. 2 is the plan view of FIG. 1 after the connector on the module meets the corresponding connector and a landing on a handle pivotally coupled to the module is aligned with a catch in a spring latch assembly on the chassis.

FIG. 3 is a perspective view of the module and chassis of FIG. 2 with the handle in an open position to align a landing on the handle with the catch in the spring latch assembly.

FIG. 4 is a cross-sectional side view of the module and chassis with the handle being rotated from the open an aligned position illustrated in FIGS. 2 and 3 to an intermediate position to engage the landing of the handle with the catch of the spring latch assembly.

FIG. 5 is the cross-sectional side view of FIG. 4 showing the handle being pivoted further to a closed position where the spring head of the spring latch assembly is displaced against spring elements to impart a reactive force through the handle and the pivot pin to the module.

FIG. 6 is the plan view of FIGS. 1 and 2 after the connector on the leading end of the module is fully connected to the corresponding connector in the chassis bay by application of the reactive force on the module using the spring latch assembly and handle.

### DETAILED DESCRIPTION OF THE INVENTION

The present invention provides a system comprising a module having a connector at a leading end of the module and a handle pivotally coupled to a trailing end of the module to pivot between an open position and a closed position, wherein the handle has a landing and a grip portion. The system further comprises a chassis having a bay, a connector disposed at a distal end of the bay, and a spring latch assembly connected to the chassis adjacent a proximal end of the bay, wherein the proximal end of the bay is open to receive the leading end of the module, and wherein the spring latch has a catch adjacent to a spring element. Receiving the leading end of the module into the bay to a first position aligns the connector on the module with the connector in the bay of the chassis and aligns the landing of the handle with the catch of the spring latch assembly. With the module in the first position in the bay, pivoting the handle from the open position to the closed position causes the landing of the handle to engage the catch of the spring latch assembly and then load the spring element, wherein loading the spring element imparts a reactive force to engage the connector on the module with the aligned connector disposed in the distal end of the bay.

The grip portion of the handle, located on a first side of the pivotal connection of the handle to the module, is preferably substantially longer than the portion of the handle adjacent to the landing. The longer grip portion provides the handle to substantially leverage a force applied to the grip portion of the handle and produce the reactive force to engage the connector on the module with the aligned connector in the bay of the chassis.

Non-limiting examples of the spring element include a coil spring, a leaf spring, a tension spring, a torsion spring, a clock spring, and combinations thereof. Optionally, the latch assembly comprises a plurality of spring elements. For example, having a spring element on each side of the catch may allow the latch assembly to operate smoothly. Another latch assembly may include multiple spring elements on each side of the catch, in order to apply a greater reaction force for mating the connectors.

In a further embodiment, the module may include a recess therein to receive at least a portion of the handle in the closed position. The handle and the recess are preferably offset to one side of the module. When the handle and recess are offset, the spring latch assembly may also be offset from the bay into which the module is to be received in order to for the handle to align with the catch in the spring latch assembly.

When the module is received into the bay, the connector on the module and the connector in the bay should be aligned in a direction in which the module is received into the bay. Accordingly, securing the module with the spring latch assembly will cause the connectors to become fully connected. Similarly, when the module has been received into the bay a sufficient distance to reach a first position, the landing of the handle is laterally aligned with the catch of the spring latch assembly. After the landing of the handle engages the catch of the spring latch assembly, pivoting the handle to the closed position moves the module from the first position within the bay of the chassis to a second position that is further within the bay than the first position.

In another embodiment of the apparatus of the present invention, the module is installable in the bay of the chassis to dispose a connector on the module in electronic engagement with a connector on a midplane in the chassis. The module may be, for example, a server blade, a network switch, a power supply, a management module, or some other electronic device.

In one embodiment of the apparatus and system of the present invention, the electronic module is slidably receivable into the bay of the chassis to align the connector on the leading end of the electronic module with a corresponding connector extending from a midplane and into the bay of the chassis using a slidable coupling between the module and the chassis bay. For example, but not by way of limitation, the slidable coupling may comprise a bracket mounted on a wall of the chassis and a follower mounted on the module to slidably engage the bracket to enable sliding movement of the module relative to the chassis and between a first position with the leading end of the module adjacent to the connector the midplane and a second position with a connector on the leading end of the module fully engaged with a corresponding connector on the midplane. In a related embodiment, the bracket on the chassis may comprise a portion that protrudes from the chassis and the follower on the module may comprise an elongate recess on the module to slidably receive the portion protruding from the chassis.

In another embodiment of the apparatus and system of the present invention, the chassis comprises a plurality of bays and is adapted to receive a plurality of electronic modules therein, each module having a connector thereon, to be installed in the chassis to electronically couple with a plurality of corresponding connectors on a midplane connected to the chassis.

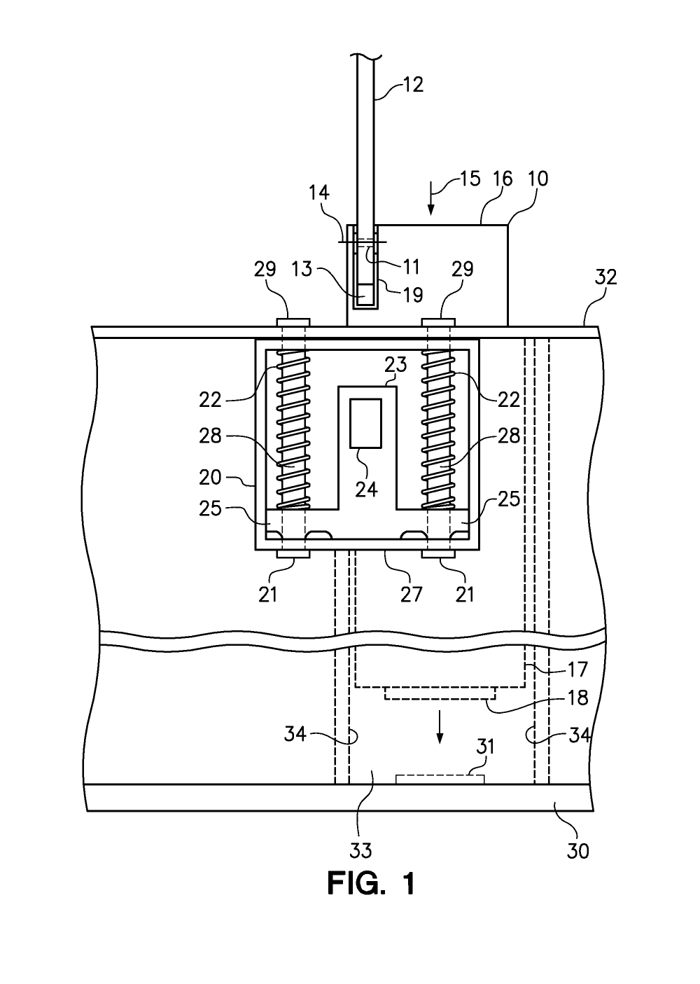

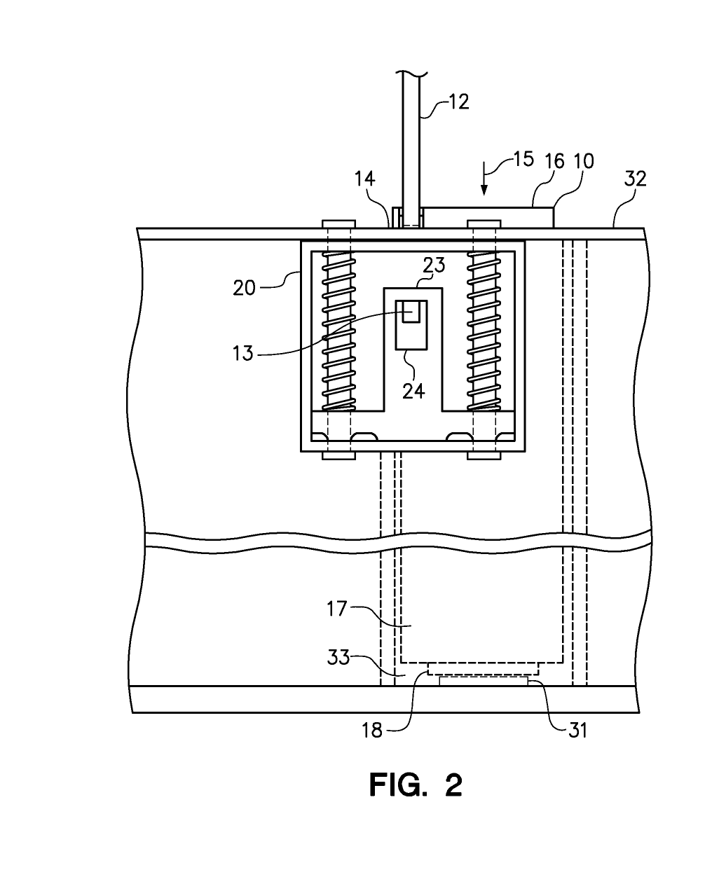

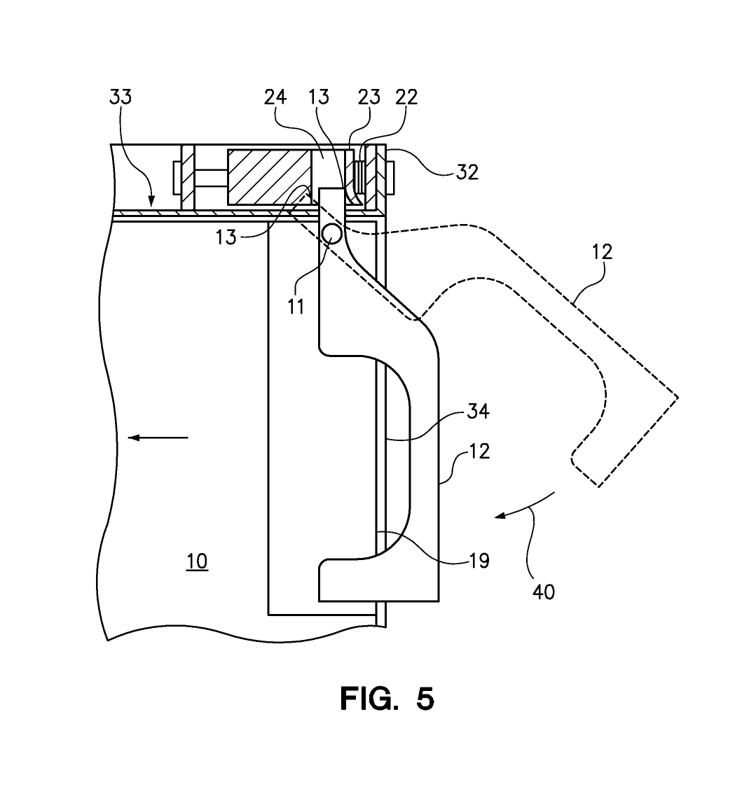

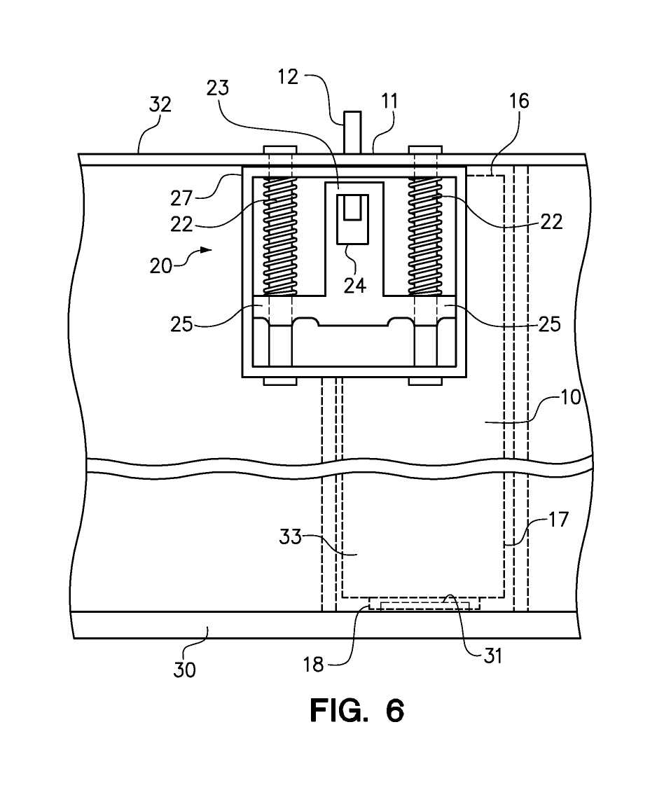

FIG. 1 is a plan view of an embodiment of a chassis 32 having a bay 33 receiving a leading end 17 of an electronic module 10 to position a connector 18 on the leading end 17 of the module 10 in alignment with a corresponding connector 31 extending into the bay 33 from a midplane 30 secured within the chassis 32. The bay 33 is intermediate two adjacent and parallel walls or other guiding members 34 in the chassis 32. The module 10 further comprises a trailing end 16 with a handle 12 pivotally coupled to the module 10 at a pin 11 to enable the handle 12 to pivot about an axis 14 of the pin 11. The handle 12 further comprises a landing 13. The handle 12 is pivotal between an open position, illustrated in FIGS. 1-3, and a closed position, illustrated in FIGS. 5 and 6. The module 10 may also include a recess 19 to receive at least a portion of the handle 12 when the handle is in the closed position. The module 10 is easily insertable and slidable within the bay 33 in the direction of the arrow 15 to the position illustrated in FIG. 2.

The embodiment of a spring latch assembly 20 of FIG. 1 comprises a frame 27, a pair of posts 28, each having a leading head 21 and a trailing head 29. Each post 28 has a spring element 22 received thereon and captured intermediate the frame 27 and a shoulder 25 of a spring head 23. The spring head 23 comprises a catch 24 therein to receive the landing 13 of the handle 12 on the module 10.

FIG. 2 is the plan view of FIG. 1 after the connector 18 on the leading end 17 of the module 10 is positioned in close proximity with the corresponding connector 31 extending into the bay 33 of the chassis 32 from a midplane 30. The landing 13 on the handle 12 pivotally coupled to the module 10 is vertically aligned with the catch 24 in the spring head 23 of the spring latch assembly 20 connected to the chassis 32. A portion of the trailing end 16 of the module 10 remains outside the bay 33 of the chassis 32. It will be understood that the module 10 is easily slidable into the bay 33 of the chassis 32 without substantial resistance until it reaches the position illustrated in FIG. 2, and that the resistance to further movement of the module 10 in the direction of arrow 15, which requires engaging the connector 18 on the leading end 17 of the module 10 with the corresponding connector 31 on the midplane 30, requires a substantially greater amount of force than is required to slide the module 10 within the bay 33 to the position illustrated in FIG. 2. It should be appreciated that the operation of the latch assembly is not dependent upon orientation, such that the vertical alignment shown may be any lateral alignment in other configurations.

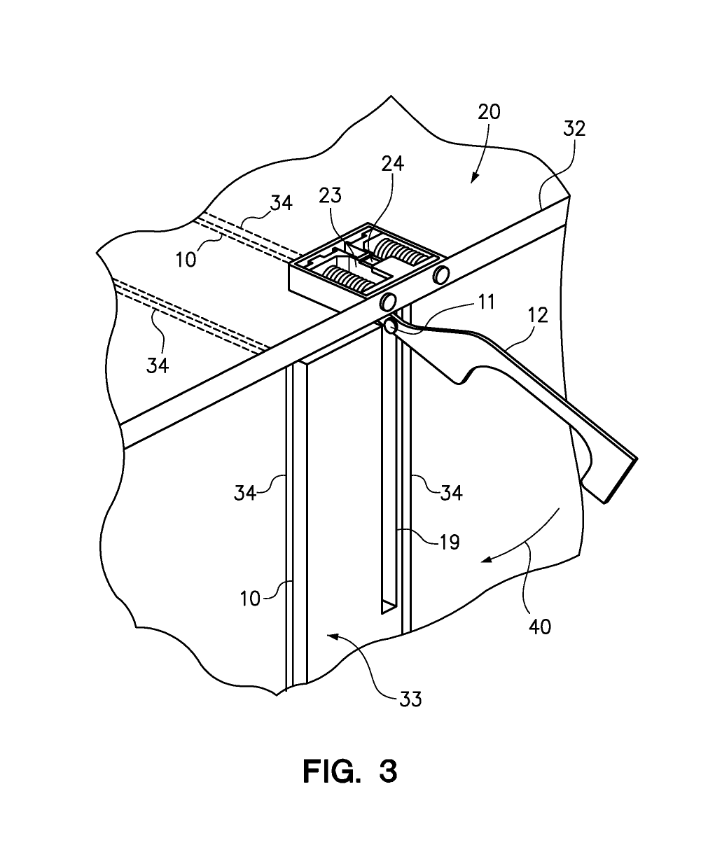

FIG. 3 is a perspective view of the bay 33 of the chassis 32, as defined by the adjacent walls 34, with the module 10 received to the position illustrated in FIG. 2. The handle 12 on the module 10 is illustrated in an open position with the landing 13 (not shown in FIG. 3—see FIGS. 1 and 2) aligned with the catch 24 in the spring head 23 of the spring latch assembly 20 on the chassis 32. From the position illustrated in FIGS. 2 and 3, pivoting of the handle 12 about the pin 11 from the open position shown in FIGS. 2 and 3 and in the direction of arrow 40 and towards the recess 19 will engage the landing 13 (not shown in FIG. 3—see FIGS. 1 and 2) with the catch 24 in the spring latch assembly 20.

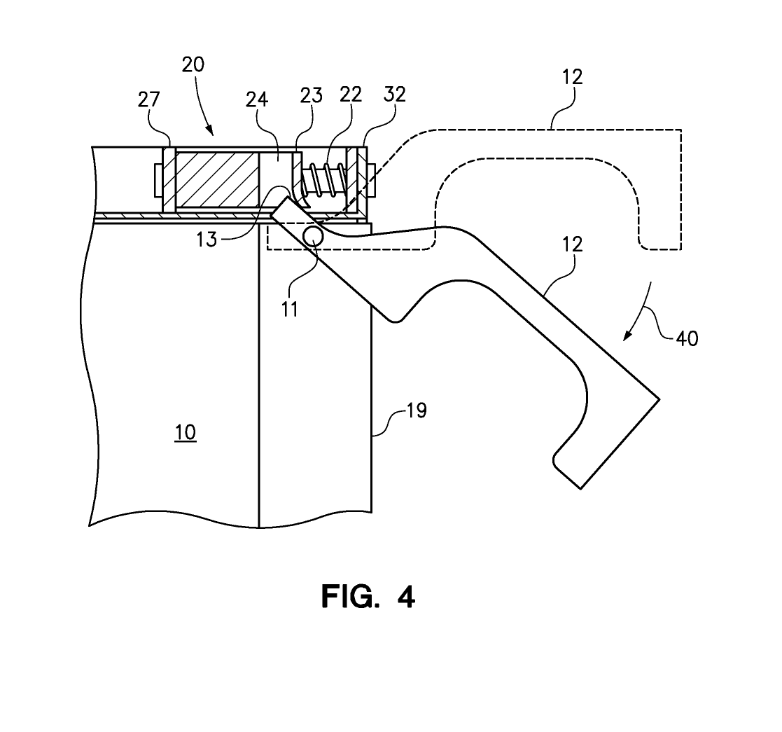

FIG. 4 is a side elevation view of the handle 12 on the module 10 pivoted about the pin 11 to an intermediate position to engage the landing 13 with the catch 24 of the spring head 23 of the spring latch assembly 20 connected to the chassis 32. FIG. 4 illustrates the interaction between the handle 12 and the spring latch assembly 20 as the handle 12 pivots in the direction of arrow 40 from the open position (shown in dotted lines in FIG. 4) to the intermediate position (shown with solid lines in FIG. 4). The landing 13 engages the catch 24 and displaces the spring head 23 to compress the spring elements 22 between the frame 27 and the spring head 23 to load the spring elements 22 as the handle 12 pivots in the direction of arrow 40 towards the recess 19.

FIG. 5 is the side elevation view of FIG. 4 after the handle 12 is rotated further in the direction of arrow 40 to further displace the spring head 23 against the spring elements 22 to impart a reactive force through the pin 11 to the module 10. The handle 12 shown in solid lines in FIG. 5 illustrates the closed position to secure the module 10 within the bay 33 of the chassis 32. As a result of the reactive force on the module 10, the module 10 has moved further into the bay 33.

FIG. 6 is the plan view of FIGS. 1 and 2 after the connector 18 on the leading end 17 of the module 10 is fully engaged with the corresponding connector 31 in the bay 33 of the chassis 32. The handle 12 is illustrated in the closed position to lie generally along the trailing end 16 of the module 10 and partially within the recess 19 (not shown) of the module 10. The spring head 23 is displaced to move and compress the spring elements 22 between the shoulders 25 of the spring head 23 and the frame 27. The resulting reactive force imparted by the spring latch assembly 20 through the handle 12 and the pin 11 to the module 10 urge the connector 18 of the module 10 into engagement with the corresponding connector 31 on the midplane 30.

It will be understood that the spring latch assembly 20 may comprise two coiled spring elements 22, as illustrated in FIGS. 1-3 and 6, a single spring element, or any number of spring elements greater than two. It will be further understood that the spring elements may comprise a leaf spring, a tension spring, a torsion spring, a clock spring or, in other embodiments, a resilient body of a material having spring-like properties.

It should be appreciated that one advantage of the spring latch assembly of the present invention is that a generally uniform mating force can be applied between the two connectors 18, 31 over a range of distance. Accordingly, where dimensional tolerances of various components, such as the chassis, the midplane, the module and the connectors themselves, add up to large potential deviations from one installation to another, the spring latch assembly will accommodate a wide range of dimensions yet applied a generally uniform mating force.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, components and/or groups, but do not preclude the presence or addition of one or more other features, integers, steps, operations, elements, components, and/or groups thereof. The terms “preferably,” “preferred,” “prefer,” “optionally,” “may,” and similar terms are used to indicate that an item, condition or step being referred to is an optional (not required) feature of the invention.

The corresponding structures, materials, acts, and equivalents of all means or steps plus function elements in the claims below are intended to include any structure, material, or act for performing the function in combination with other claimed elements as specifically claimed. The description of the present invention has been presented for purposes of illustration and description, but it not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A system, comprising:
a module having a connector at a leading end of the module and a handle pivotally coupled to a trailing end of the module to pivot between an open position and a closed position, wherein the handle has a landing and a grip portion;
a chassis having a bay, a connector disposed at a distal end of the bay, and a spring latch assembly connected to the chassis adjacent a proximal end of the bay, wherein the proximal end of the bay is open to receive the leading end of the module, and wherein the spring latch has a catch adjacent to a spring element;
wherein receiving the leading end of the module into the bay to a first position aligns the connector on the module with the connector in the bay of the chassis and aligns the landing of the handle with the catch of the spring latch assembly;
wherein pivoting the handle from the open position to the closed position, with the module in the first position in the bay, causes the landing of the handle to engage the catch of the spring latch assembly and then load the spring element, wherein loading the spring element imparts a reactive force to engage the connector on the module with the aligned connector disposed in the distal end of the bay.

2. The system of claim 1, wherein the grip portion of the handle is substantially longer on a first side of the pivotal connection of the handle to the module than the portion of the handle adjacent to the landing to substantially leverage a force applied to the grip portion of the handle and produce the reactive force to engage the connector on the module with the aligned connector in the bay of the chassis.

3. The system of claim 1, wherein the spring element comprises a plurality of spring elements.

4. The system of claim 3, wherein the spring element comprises one of a coil spring, a leaf spring, a tension spring, a torsion spring, a clock spring and a combination of these springs.

5. The system of claim 1, wherein the module comprises a recess therein to receive at least a portion of the handle in the closed position.

6. The system of claim 1, wherein the spring latch assembly is offset from the bay into which the module is to be received to align the handle with a recess in the module.

7. The system of claim 1, wherein the connector at the leading end of the module is a pin and sleeve connector and the connector disposed at the distal end of the bay is a corresponding pin and sleeve connector.

8. The system of claim 1, wherein the connector on the module and the connector in the bay are aligned in a direction in which the module is received into the bay.

9. The system of claim 8, wherein the landing of the handle is laterally aligned with the catch of the spring latch assembly when the module is in the first position.

10. The system of claim 1, wherein pivoting the handle from the open position to the closed position, with the landing of the handle engaged with the catch of the spring latch assembly, moves the module from the first position within the bay of the chassis to a second position that is further within the bay than the first position.
